(19) United States
(12) Patent Application Publication
(10) Pub. No.: US 2006/0211388 A1
(43) Pub. Date: Sep. 21, 2006

(54) Stackable printed circuit boards

(76) Inventors: Grady D. Lambert, Groton, MA (US); Ryan C. McDaniel, Hudson, MA (US); Phil Kaminski, Manchester, NH (US)

Correspondence Address: PERKINS COIE LLP, P.O. BOX 2168, MENLO PARK, CA, 94026, US

(21) Appl. No.: 11/075,406

(22) Filed: Mar. 7, 2005

(51) Int. Cl. H03D 7/16

(52) U.S. Cl. 455/131

(57) ABSTRACT

A system, method and apparatus is provided for stackable printed circuit boards. In one embodiment, the invention is an apparatus. The apparatus includes a FLASH memory module. The memory module includes a printed circuit (p.c.) board. The memory module also includes a first connector attached to the p.c. board. The memory module further includes a second connector attached to the p.c. board. The memory module also includes a FLASH memory coupled to the p.c. board. The FLASH memory is electrically coupled to the first connector. The FLASH memory is electrically isolated from the second connector. In an alternate embodiment, the invention is a method. The method includes receiving a signal for a first p.c. board. Furthermore, the method includes operating the first p.c. board based on the signal for the first p.c. board. Moreover, the method includes receiving a signal at the first p.c. board for a second p.c. board. Additionally, the method includes transferring the signal for the second p.c. board to the second p.c. board. Also, the method includes operating the second p.c. board based on the signal for the second p.c. board.

### CROSS-REFERENCE TO RELATED APPLICATION

Application Ser. No. ______, entitled “CONFIGURED PRINTED CIRCUIT BOARDS”, having attorney docket number 54385-8002.US01 and filed on the same date as this application is hereby incorporated herein by reference as if fully set forth herein. Application Ser. No. ______, entitled “EXTENDED UNIVERSAL SERIAL BUS CONNECTIVITY”, having attorney docket number 54385-8004.US01 and filed on the same date as this application is also hereby incorporated herein by reference as if fully set forth herein.

### BACKGROUND

Printed circuit boards in general are well known and well understood. They are used for computer and other electrical components, have been designed to withstand severe environmental circumstances, and are the backbone from which much embedded computer technology springs. A printed circuit board thus has many potential applications.

As semiconductor chips and related technology appear and are accepted in more diverse applications, the need to pack more functionality into a given space arises. For example, where a single printed circuit board with limited associated functionality would have been acceptable in an initial design, a follow-on product may be expected to integrate much more computer technology, requiring more and more complex printed circuit boards. Moreover, while the first included printed circuit board may be a luxury for which space and other allowances are made, later products may have design constraints calling for smaller (and potentially more rugged) printed circuit boards (along with additional functionality). Thus, finding a way to fit more printed circuit boards and more functionality into a given space may be useful. Moreover, providing more rugged connections between printed circuit boards may be useful.

In some applications, multiple printed circuit boards may have independent functions, and have little or nothing in common. Moreover, multiple printed circuit boards of the same type may be needed, but communication between components of those printed circuit boards may not be desirable. Thus, providing printed circuit boards that can fit in a small space and operate independently may be useful.

### SUMMARY

A system, method and apparatus is provided for stackable printed circuit boards. In one embodiment, the invention is an apparatus. The apparatus includes a FLASH memory module. The memory module includes a printed circuit (p.c.) board. The memory module also includes a first connector attached to the p.c. board. The memory module further includes a second connector attached to the p.c. board. The memory module also includes a FLASH memory coupled to the p.c. board. The FLASH memory is electrically coupled to the first connector. The apparatus may further include a FLASH controller coupled to the FLASH memory and coupled to the first connector. The FLASH controller is electrically interposed between the FLASH memory and the first connector. In the apparatus, the FLASH memory may be a single integrated circuit. In the apparatus, the FLASH memory may also be a set of multiple integrated circuits. In the apparatus, the first connector may include connections for a USB bus. Similarly, in the apparatus, the second connector may include connections for a USB bus.

The first p.c. board may have a first surface and a second surface. The second surface is opposite the first surface, and the first connector and the second connector may both be attached to the first surface. The apparatus may further include a third connector attached to the second surface of the first p.c. board. The third connector may be electrically coupled to the second connector and physically aligned with the second connector. The apparatus may also include a fourth connector attached to the second surface of the first p.c. board. The fourth connector may be electrically coupled to the first connector and physically aligned with the first connector. The FLASH memory is electrically isolated from the second connector.

In another embodiment, the invention is an apparatus. The apparatus includes a FLASH memory module capable of communicating on a USB bus. The memory module includes a printed circuit (p.c.) board. The memory module also includes a first connector attached to the p.c. board. The memory module further includes a second connector attached to the p.c. board. The memory module also includes a FLASH memory coupled to the p.c. board. The FLASH memory is electrically coupled to the first connector. The FLASH memory is electrically isolated from the second connector.

In an alternate embodiment, the invention is a method. The method includes receiving a signal for a first p.c. board. Furthermore, the method includes operating the first p.c. board based on the signal for the first p.c. board. Moreover, the method includes receiving a signal at the first p.c. board for a second p.c. board. Additionally, the method includes transferring the signal for the second p.c. board to the second p.c. board. Also, the method includes operating the second p.c. board based on the signal for the second p.c. board.

In yet another alternate embodiment, the invention is an apparatus. The apparatus includes a p.c. board. The apparatus also includes a first connector physically connected to the p.c. board. The apparatus further includes a second connector physically connected to the p.c. board. The apparatus also includes an active component coupled to the p.c. board. The active component is electrically coupled to the first connector. The active component is electrically isolated from the second connector.

In the apparatus, the active component may be FLASH memory. Furthermore, the apparatus may include a FLASH controller coupled to the FLASH memory and coupled to the first connector. The FLASH controller may be electrically interposed between the FLASH memory and the first connector.

Moreover, the apparatus may involve the p.c. board having a first surface and a second surface. The first surface is opposite the second surface, the first connector and the second connector are both connected to the first surface. The apparatus may further include a third connector connected to the second surface of the p.c. board. The third connector may be electrically coupled to the second connector and the third connector may be physically aligned with the second connector. Similarly, the apparatus may further include a fourth connector connected to the second surface of the p.c. board. The fourth connector may be electrically coupled to the first connector and the fourth connector may be physically aligned with the first connector.

Further, in the apparatus, the p.c. board may be a first p.c. board. The apparatus may also include a second p.c. board having a first surface and a second surface, with the second surface opposite the first surface. Moreover, the apparatus may include a fifth connector physically connected to the first surface of the second p.c. board and connected to the third connector. Also, the apparatus may include a FLASH memory coupled to the second p.c. board, and electrically coupled to the fifth connector.

Additionally, the apparatus may include a sixth connector attached to the first surface of the second p.c. board. The sixth connector may be electrically isolated from the FLASH memory and connected to the fourth connector. Similarly, the apparatus may include a seventh connector attached to the second surface of the second p.c. board. The seventh connector may be electrically coupled to the sixth connector and physically aligned with the sixth connector. Moreover, the apparatus may include an eighth connector attached to the second surface of the second p.c. board, electrically coupled to the fifth connector, and physically aligned with the fifth connector.

In some embodiments, the first p.c. board is in a first configuration and the second p.c. board is in a second configuration. Moreover, in some embodiments, the first configuration is related to the second configuration by way of a 180 degree physical rotation. Similarly, in other embodiments, the first configuration and the second configuration are determined through physical configuration of a component attached to the first p.c. board and a component attached to the second p.c. board. Also, in some embodiments, the first p.c. board and attached components provide a first addressable drive and the second p.c. board and attached components provide a second addressable drive.

In yet another alternate embodiment, the invention is an apparatus. The apparatus is a USB compatible module. The apparatus includes a p.c. board. The apparatus also includes a first connector physically connected to the p.c. board. The apparatus further includes a second connector physically connected to the p.c. board. The apparatus also includes an active component coupled to the p.c. board. The active component is electrically coupled to the first connector. The active component is electrically isolated from the second connector.

In still another alternate embodiment, the invention is an apparatus. The apparatus includes means for supporting components. Also, the apparatus includes first means for connecting attached to the means for supporting components. Further, the apparatus includes second means for connecting attached to the means for supporting components. Moreover, the apparatus includes means for storing data. The means for storing data is electrically coupled to the first means for connecting, and the means for storing data is electrically isolated from the second means for connecting.

In yet another alternate embodiment, the invention is an apparatus. The apparatus includes means for supporting components. Also, the apparatus includes first means for connecting attached to the means for supporting components. The first means is for communicating with a USB bus. Further, the apparatus includes second means for connecting attached to the means for supporting components. Moreover, the apparatus includes means for storing data. The means for storing data is electrically coupled to the first means for connecting, and the means for storing data is electrically isolated from the second means for connecting.

### BRIEF DESCRIPTION OF THE DRAWINGS

The present invention is illustrated in an exemplary manner by the accompanying drawings. The drawings should be understood as exemplary rather than limiting, as the scope of the invention is defined by the claims.

FIG. 1 illustrates an embodiment of a set of stacked printed circuit boards.

FIG. 2 illustrates another embodiment of a system which includes a set of stacked printed circuit boards.

FIG. 3 illustrates yet another embodiment of a set of printed circuit boards which may implement a set of stacked modules.

FIG. 4 illustrates an embodiment of a system.

FIG. 5 illustrates an embodiment of a flash memory module such as may be used in these systems for example.

FIG. 6A illustrates a bottom view of an embodiment of a module and the connectors used therein.

FIG. 6B illustrates a top view of the module of FIG. 6A.

FIG. 7 illustrates a side or cross-cut view of a printed circuit board in one embodiment.

FIG. 8A illustrates an embodiment of a process of preparing a printed circuit board.

FIG. 8B illustrates an embodiment of a process for installing and using various devices.

FIG. 8C illustrates an embodiment of a process of operating modules in a system.

### DETAILED DESCRIPTION

A system, method and apparatus is provided for stackable printed circuit boards. The specific embodiments described in this document represent exemplary instances of the present invention, and are illustrative in nature rather than restrictive in terms of the scope of the present invention. The scope of the invention is defined by the claims.

In some embodiments, the invention is an apparatus. The apparatus includes first and second printed circuit boards. The first printed circuit board includes a connector associated with the active components of the first printed circuit board, and a set of connectors associated with a passthrough for signals not associated with the first printed circuit board. The second printed circuit board also includes a connector associated with the active components of the second printed circuit board, and that connector is connected to the passthrough of the first printed circuit board. Moreover, a set of connectors on the second printed circuit board may also be provided as a passthrough, thus allowing the first and second printed boards to be fabricated identically. Also, both printed circuit boards may have an additional connector associated with the active components of the printed circuit board, or simply provided to connect with a passthrough on another printed circuit board. Thus, a mechanically stable system may be provided, allowing for independent operation of multiple printed circuit boards which are connected together.

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments.

In one embodiment, the invention is an apparatus. The apparatus includes a FLASH memory module. The memory module includes a printed circuit (p.c.) board. The memory module also includes a first connector attached to the p.c. board. The memory module further includes a second connector attached to the p.c. board. The memory module also includes a FLASH memory coupled to the p.c. board. The FLASH memory is electrically coupled to the first connector. The apparatus may further include a FLASH controller coupled to the FLASH memory and coupled to the first connector. The FLASH controller is electrically interposed between the FLASH memory and the first connector. In the apparatus, the FLASH memory may be a single integrated circuit. In the apparatus, the FLASH memory may also be a set of multiple integrated circuits. In the apparatus, the first connector may include connections for a USB bus. Similarly, in the apparatus, the second connector may include connections for a USB bus.

The first p.c. board may have a first surface and a second surface. The second surface is opposite the first surface, and the first connector and the second connector may both be attached to the first surface. The apparatus may further include a third connector attached to the second surface of the first p.c. board. The third connector may be electrically coupled to the second connector and physically aligned with the second connector. The apparatus may also include a fourth connector attached to the second surface of the first p.c. board. The fourth connector may be electrically coupled to the first connector and physically aligned with the first connector.

The FLASH memory is electrically isolated from the second connector.

In another embodiment, the invention is an apparatus. The apparatus includes a FLASH memory module capable of communicating on a USB bus. The memory module includes a printed circuit (p.c.) board. The memory module also includes a first connector attached to the p.c. board. The memory module further includes a second connector attached to the p.c. board. The memory module also includes a FLASH memory coupled to the p.c. board. The FLASH memory is electrically coupled to the first connector. The FLASH memory is electrically isolated from the second connector.

In an alternate embodiment, the invention is a method. The method includes receiving a signal for a first p.c. board. Furthermore, the method includes operating the first p.c. board based on the signal for the first p.c. board. Moreover, the method includes receiving a signal at the first p.c. board for a second p.c. board. Additionally, the method includes transferring the signal for the second p.c. board to the second p.c. board. Also, the method includes operating the second p.c. board based on the signal for the second p.c. board.

In yet another alternate embodiment, the invention is an apparatus. The apparatus includes a p.c. board. The apparatus also includes a first connector physically connected to the p.c. board. The apparatus further includes a second connector physically connected to the p.c. board. The apparatus also includes an active component coupled to the p.c. board. The active component is electrically coupled to the first connector. The active component is electrically isolated from the second connector.

In the apparatus, the active component may be FLASH memory. Furthermore, the apparatus may include a FLASH controller coupled to the FLASH memory and coupled to the first connector. The FLASH controller may be electrically interposed between the FLASH memory and the first connector.

Moreover, the apparatus may involve the p.c. board having a first surface and a second surface. The first surface is opposite the second surface, the first connector and the second connector are both connected to the first surface. The apparatus may further include a third connector connected to the second surface of the p.c. board. The third connector may be electrically coupled to the second connector and the third connector may be physically aligned with the second connector. Similarly, the apparatus may further include a fourth connector connected to the second surface of the p.c. board. The fourth connector may be electrically coupled to the first connector and the fourth connector may be physically aligned with the first connector.

Further, in the apparatus, the p.c. board may be a first p.c. board. The apparatus may also include a second p.c. board having a first surface and a second surface, with the second surface opposite the first surface. Moreover, the apparatus may include a fifth connector physically connected to the first surface of the second p.c. board and connected to the third connector. Also, the apparatus may include a FLASH memory coupled to the second p.c. board, and electrically coupled to the fifth connector.

Additionally, the apparatus may include a sixth connector attached to the first surface of the second p.c. board. The sixth connector may be electrically isolated from the FLASH memory and connected to the fourth connector. Similarly, the apparatus may include a seventh connector attached to the second surface of the second p.c. board. The seventh connector may be electrically coupled to the sixth connector and physically aligned with the sixth connector. Moreover, the apparatus may include an eighth connector attached to the second surface of the second p.c. board, electrically coupled to the fifth connector, and physically aligned with the fifth connector.

In some embodiments, the first p.c. board is in a first configuration and the second p.c. board is in a second configuration. Moreover, in some embodiments, the first configuration is related to the second configuration by way of a 180 degree physical rotation. Similarly, in other embodiments, the first configuration and the second configuration are determined through physical configuration of a component attached to the first p.c. board and a component attached to the second p.c. board. Also, in some embodiments, the first p.c. board and attached components provide a first addressable drive and the second p.c. board and attached components provide a second addressable drive.

In yet another alternate embodiment, the invention is an apparatus. The apparatus is a USB compatible module. The apparatus includes a p.c. board. The apparatus also includes a first connector physically connected to the p.c. board. The apparatus further includes a second connector physically connected to the p.c. board. The apparatus also includes an active component coupled to the p.c. board. The active component is electrically coupled to the first connector. The active component is electrically isolated from the second connector.

In still another alternate embodiment, the invention is an apparatus. The apparatus includes means for supporting components. Also, the apparatus includes first means for connecting attached to the means for supporting components. Further, the apparatus includes second means for connecting attached to the means for supporting components. Moreover, the apparatus includes means for storing data. The means for storing data is electrically coupled to the first means for connecting, and the means for storing data is electrically isolated from the second means for connecting.

In yet another alternate embodiment, the invention is an apparatus. The apparatus includes means for supporting components. Also, the apparatus includes first means for connecting attached to the means for supporting components. The first means is for communicating with a USB bus. Further, the apparatus includes second means for connecting attached to the means for supporting components. Moreover, the apparatus includes means for storing data. The means for storing data is electrically coupled to the first means for connecting, and the means for storing data is electrically isolated from the second means for connecting.

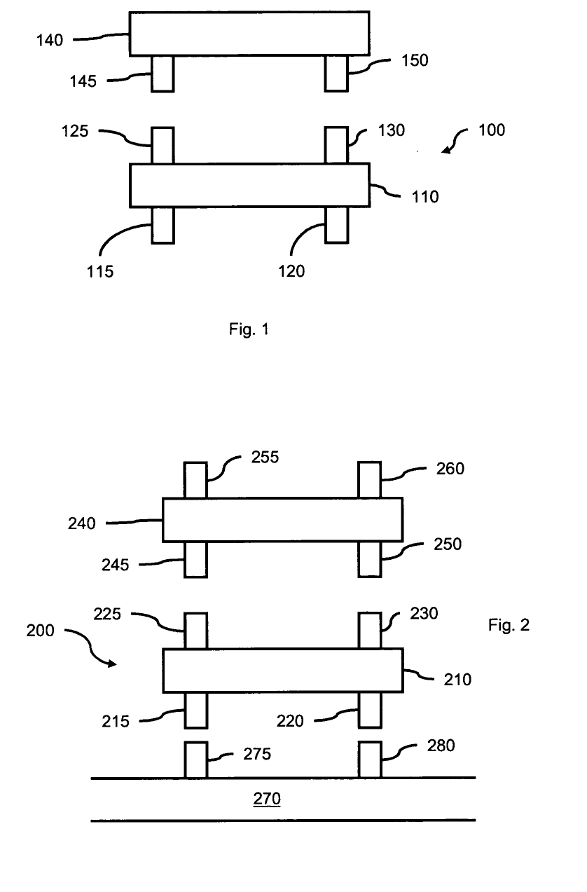

Reference to the illustrations may provide further details of various embodiments. FIG. 1 illustrates an embodiment of a set of stacked printed circuit boards. System 100 includes first and second printed circuit board which are connected together through connectors which allow for independent communication with components on the boards. System 100 includes a first printed circuit board 110 which has on the lower surface connectors 115 and 120. Board 110 also has on an upper surface connectors 125 and 130. Printed circuit board 110 may be, for example, a flash memory module useful for providing memory or a solid state disk or disk drive in a computer or similar system. Shown above board 110 is printed circuit board 140, which also has attached to it on a lower surface connectors 145 and 150. Thus printed circuit board 140 may be attached to printed circuit board 110 through connectors 145, 150, 125 and 130 to provide a serially stacked set of printed circuit boards.

In one embodiment, printed circuit board 140 is also a flash memory module. Furthermore, in one embodiment, connector 120 is electrically coupled to active components of printed circuit board 110. Connector 115 is electrically isolated from components of printed circuit board 110 except for connector 125. Connectors 115 and 125 along with, for example, through holes of printed circuit board 110 provide a pass-through for signals. Thus connector 145 and circuit board 140 may receive signals directly through connectors 115 and 125, and then connector 145 of printed circuit board 140 may pass those signals to active components of printed circuit board 140.

In one embodiment, printed circuit board 140 is essentially identical to printed circuit board 110 except that when they are mated or connected, printed circuit board 140 is rotated 180 degrees relative to printed circuit board 110. Thus, connector 145 corresponds to connector 120, and connector 150 corresponds to connector 115 in terms of their function and connections and couplings within the board. However, connector 145 is aligned above connector 115 and connector 150 is aligned above connector 120.

Alternative embodiments of the printed circuit boards may also be implemented. FIG. 2 illustrates another embodiment of a system which includes a set of stacked printed circuit boards. Similarly to FIG. 1, FIG. 2 includes system 200 which includes first and second printed circuit boards stacked above yet another main or system printed circuit board and also includes connectors between the various printed circuit boards. Printed circuit board 210 includes active components which are not shown and connectors 215 and 220 which are mounted on one surface of printed circuit board 210. Printed circuit board 210 also includes connectors 225 and 230 mounted on the second surface opposite the first surface where connectors 215 and 220 are mounted.

As described previously with respect to printed circuit board 110 of FIG. 1, connectors 225 and 215 form a pass-through for signals which are electrically isolated from active components of printed circuit board 210, whereas connector 220 is electrically coupled to active components of printed circuit board 210 which may be, for example, a flash memory module. Above printed circuit board 210 is printed circuit board 240. Printed circuit board 240 also includes active components which are not shown and includes on a first surface connectors 245 and 250 which are attached thereto. Printed circuit board 240 also includes connectors 255 and 260 attached to a second surface opposite the first surface where connectors 245 and 250 are attached.

Furthermore, printed circuit board 270 is illustrated with connectors 275 and 280 mounted on a top surface of printed circuit board 270. The exploded view of FIG. 2 shows how the printed circuit boards 210, 240 and 270 would line up. When these boards are connected, connectors 215 and 220 connect with connectors 275 and 280 of printed circuit board 270. Similarly connectors 245 and 250 connect with connectors 225 and 230 of printed circuit board 210. Thus printed circuit board 240 is connected to printed circuit board 210 which is then connected to printed circuit board 270.

In such an embodiment, connector 280 passes signals to connector 220 which is coupled to the active components of printed circuit board 210. Thus those signals are used by printed circuit board 210 as if it were a single isolated drive. Connector 275 passes signals to connector 215 which then passes signals through printed circuit board 210 to connector 225 which then passes signals to connector 245 and then to the active components of printed circuit board 240.

Thus printed circuit board 240 operates as an independent module or drive from printed circuit board 210, both of which are addressed through separate and physically or electrically isolated connectors 275 and 280. Note that in this context, electrical isolation need not involve complete isolation, and may involve a common ground plane (though probably not on the printed circuit board) while maintaining isolation of data and control signals, for example. In some embodiments, printed circuit board 240 and printed circuit board 210 are assembled essentially identically, for example, in the same manufacturing process. When mounted, printed circuit board 240 is rotated 180 degrees relative to printed circuit board 210 such that corresponding connectors are on opposite ends of the set of printed circuit boards.

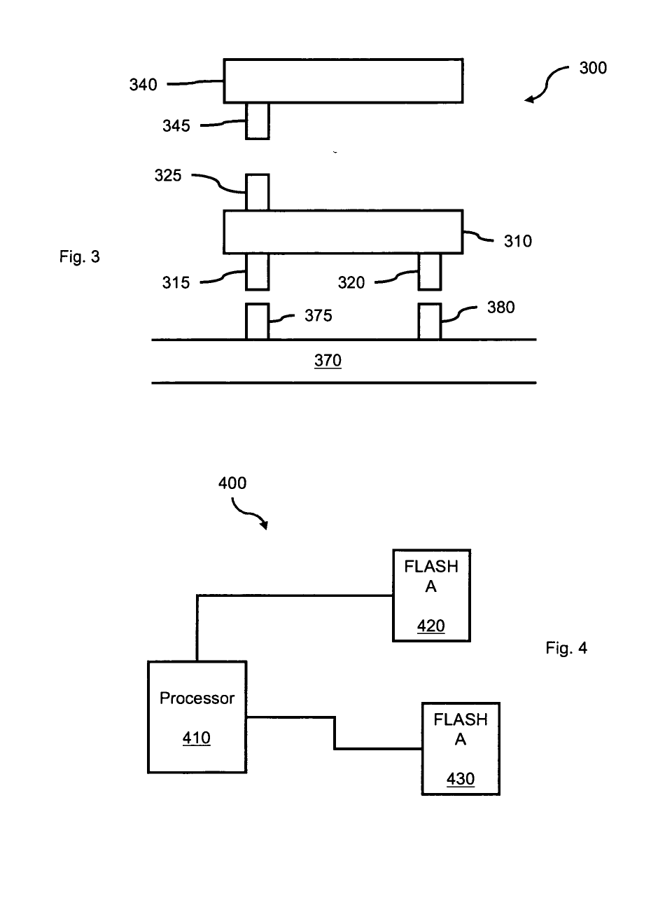

As may be expected, other embodiments may be used in some systems or applications. FIG. 3 illustrates yet another embodiment of a set of printed circuit boards which may implement a set of stacked modules. System 300 includes first and second printed circuit boards which are independent modules, and which may be mounted as a stack on a main printed circuit board, allowing for independent addressing. Printed circuit board 310 includes on a first surface connectors 315 and 320 and on the second surface opposite the first surface connector 325. Connector 320 is electrically coupled to active components on printed circuit board 310, which are not shown. Connector 315 is coupled to connector 325 electrically but is otherwise electrically isolated from the rest of the material of printed circuit board 310. Thus connectors 315 and 325 provide a pass-through for signals.

Printed circuit board 340 may be stacked on printed circuit board 310 using connector 345, which is attached to a surface of printed circuit board 340. Thus printed circuit board 340 may receive signals through connectors 315, 325 and 345. Also shown is main printed circuit board 370, which may be the rest of a system or the main board of a system, including on one surface attached connectors 375 and 380. Thus the system of printed circuit board 370 may address, for example, a flash memory drive on printed circuit board 310 through connectors 380 and 320 and another separate flash memory drive on printed circuit board 340 through connectors 375, 315, 325 and 345.

Such a system may implement a variety of different components both in terms of the base system or main system and in terms of the components on the actual stacked printed circuit boards. FIG. 4 illustrates an embodiment of one such system. System 400 includes a processor and two flash memory drives. Processor 410 is coupled to flash memory drive A, which is module 420 and flash memory drive B, which is module 430. Thus flash memory drives A and B are electrically isolated from each other and are addressed separately by the processor. However, they may occupy very close physical proximity as they may be stacked, as is shown in FIGS. 1, 2 and 3, for example. Moreover, note that a bus connecting flash memory drive A, flash memory drive B and processor 410 may be implemented even though the actual memory drives are electrically isolated otherwise.

Various modules may be used in systems which incorporate a set of stacked printed circuit boards. FIG. 5 illustrates an embodiment of a flash memory module such as may be used in these systems for example. Module 500 includes a connector, a controller, a set of flash memory chips for example, and another electrically isolated connector. Thus the view of module 500, although a logical view, is essentially that of a bottom view in one embodiment of such a module.

Connector 510 is coupled through bus 515 to controller 520. Controller 520 is a flash memory controller, for example, which is coupled to memory 530 through bus 525. Thus, controller 520 may be used to operate or control and, potentially, to marshal data coming into and out of flash memory 530. Flash memory 530 may be implemented as a single chip or as multiple chips, either packaged or bonded directly to a printed circuit board, for example. Connector 540 is also shown. Connector 540 is electrically isolated from the other components of module 500 and is used for pass-through purposes to allow signals to transfer from an underlying circuit board through module 500 to an independent module connected to module 500.

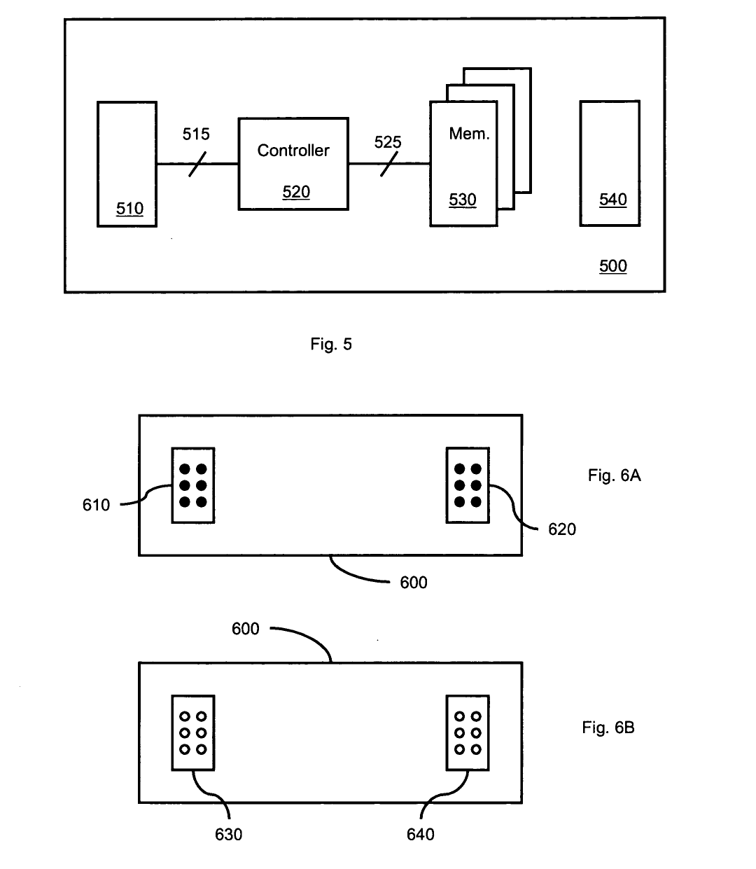

Various connectors may be used in the modules that have been described. FIG. 6A illustrates a bottom view of one such module and the connectors used therein. Module 600 includes connectors 610 and 620, both of which are referred to as male connectors as they have actual pins which may be connected to by a female connector. Thus connector 610 and connector 620 as illustrated each have six pins which may be used for transmission or receipt of signals electrically.

FIG. 6B illustrates a top view of module 600. Connectors 630 and 640 are illustrated, each of which is mounted to the top surface of module 600 as connectors 610 and 620 were mounted to the bottom surface of module 600. As illustrated, connectors 630 and 640 are female connectors having receptacles or sockets into which pins such as those of a similar connector 610 or 620 may be inserted. In such an embodiment for example, connector 630 may align with connector 610 and connector 640 may align with connector 620. Note that this alignment may not be exact. It may be approximate, thus for example, connectors 610 and 630 provide a pass-through for signals then an approximate alignment may result in signals actually being routed internally through printed circuit board 600. However, one may expect that if connectors 610 and 630 are used to form a pass-through that they will be electrically isolated from the rest of printed circuit board 600, and if the connectors are expected to be connected to each other on identical modules, that they will be aligned.

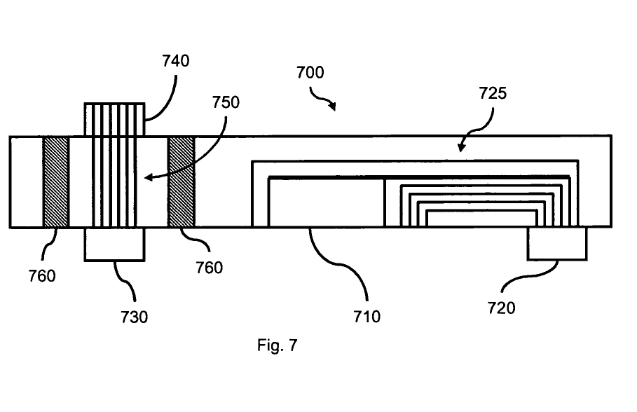

A side view of such a printed circuit board or similar printed circuit boards may also be useful. FIG. 7 illustrates a side or cross-cut view of a printed circuit board 700 in one embodiment. Printed circuit board 700 includes two connectors on the bottom side and one connector on the top side. Other components (including another connector or active components for example) may be added as appropriate. Connector 720 is mounted on the bottom side of board 710 and is a female connector with six leads coming in. As is illustrated, four of those leads are connected directly to signals. A fifth lead is connected to a ground plane and a sixth lead is connected to a power plane for example. Connector 730 is also mounted on the bottom side of board 710 and is another female connector with six leads coming in. Connector 740 is mounted on the top side of board 710. Connector 740 is a male connector with six leads extended out. As is illustrated, through-holes or internal traces are used to connect the leads of connector 730 to those of connector 740. This may be referred to as the pass-through area 750 of printed circuit board 710. Also as is illustrated, isolation areas where no traces may be found in the printed circuit board 710 are shown as area 760. Electrical isolation of connectors 730 and 740 allows for the pass-through aspect of the connectors to be used without interference with the various electrical signals otherwise created by board 710. The internal traces in board 710 are illustrated as traces 725 and may take on various different configurations and would be expected to conform to rules related to fabrication of the board and the process for doing so which are likely to result in a different representation from that illustrated in the figure.

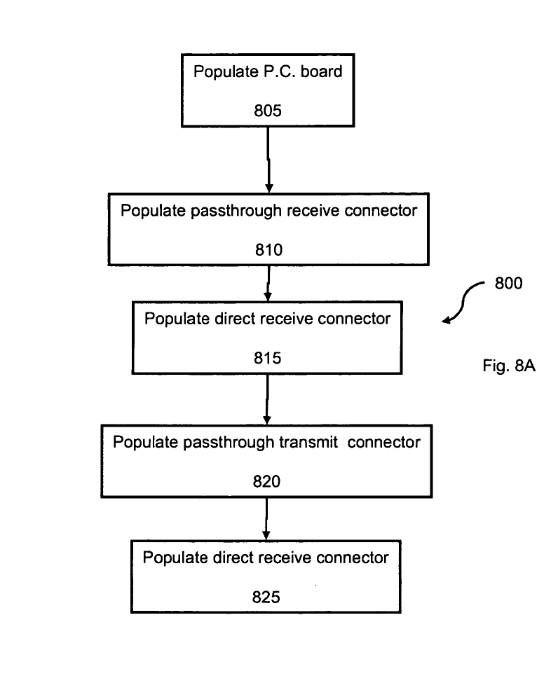

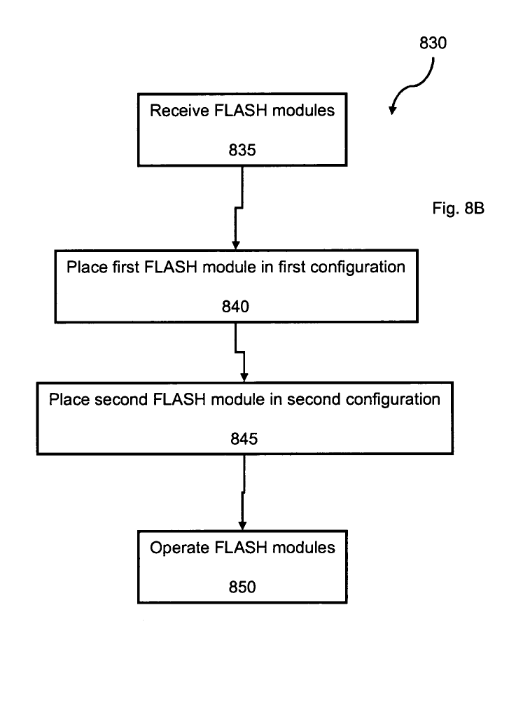

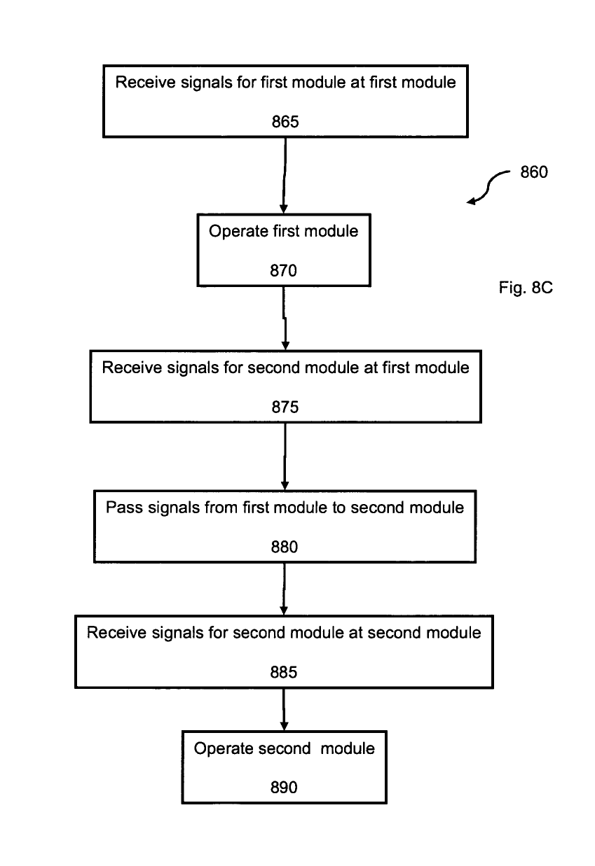

While various physical embodiments have been described, processes may also be involved in various embodiments. FIG. 8A illustrates an embodiment of a process of preparing a printed circuit board. Process 800 includes preparing a printed circuit board, populating various connectors and verifying that those connectors are properly populated, and testing the printed circuit board. Process 800 and other processes of this document are implemented as a set of modules, which may be process modules or operations, software modules with associated functions or effects, hardware modules designed to fulfill the process operations, or some combination of the various types of modules, for example. The modules of process 800 and other processes described herein may be rearranged, such as in a parallel or serial fashion, and may be reordered, combined, or subdivided in various embodiments.

Process 800 begins with module 805 where a printed circuit board is prepared such as by fabricating the various layers of the printed circuit board. At module 807, other components of the printed circuit board are populated, such as flash memory components, control components, passive components such as pull up or pull down resistors, voltage regulators and other components for example. At module 810, a pass-through receive connector is populated on the board by attaching the connector to the printed circuit board. At module 815, a direct receive connector is populated on the printed circuit board again by attaching the connector to the printed circuit board. At module 820, a pass-through transmit connector is populated on the printed circuit board on the opposite side of the pass-through receive connector and is attached thereto. Similarly at module 825, a direct transmit connector is populated on the printed circuit board opposite the direct receive connector on the same side as the pass-through transmit connector. At module 827, the printed circuit board is tested such as through electrical testing. Thus a printed circuit board is provided which has both a direct connection path, for example a connection to components on the printed circuit board and a pass-through connection path, for example allowing transmission of a pass-through signal from one side of the printed circuit board to the other side without actually having the signals interact with other components of the printed circuit board.

Similarly operation or installation of various devices may be involved in various embodiments. FIG. 8B illustrates an embodiment of a process for installing and using the various devices. Process 830 involves receiving modules, placing a first module and a first configuration and a second module on the second configuration into a system and then using those modules.

The various printed circuit boards are received at module 835. A first printed circuit board module is placed in a first configuration in a system at module 840. A first configuration may refer to a physical position or orientation. It may also refer to some form of actual configuration aspect of the system such as a jumper being placed or an on-board device or other related device being programmed for the configuration. A second printed circuit board module is placed in a second configuration onto the first printed circuit board module at module 845. Again, the second configuration may be related to a physical relationship with the first configuration or to some sort of electrical configuration for example. The printed circuit modules are operated as part of the surrounding system at module 850.

As may be expected, operation of the various printed circuit boards and other devices may be involved in some embodiments as well. FIG. 8C illustrates an embodiment of a process of operating modules in the system. Process 860 includes receiving signals from a first module, operating that first module, receiving signals for a second module, passing the signals through the first module to the second module, receiving signals for the second module at the second module, and operating the second module.

Signals are received for the printed circuit board module at that printed circuit board module at module 865. At module 870, the first printed circuit board module is operated based on the signals received at module 865. Signals for the second printed circuit board module are received at the first printed circuit board module at module 875. At module 880, signals for the second printed circuit board module are passed through the first printed circuit board module to the second printed circuit board module. The signals are received at the second printed circuit board module for use by the second printed circuit board module at module 885. Note that the second printed circuit board module would not be expected to receive signals for the first printed circuit board module in most instances. At module 890, the second printed circuit board module is operated based on the signals received there.

Similarly, features and aspects of various embodiments may be integrated into other embodiments, and embodiments illustrated in this document may be implemented without all of the features or aspects illustrated or described.

One skilled in the art will appreciate that although specific examples and embodiments of the system and methods have been described for purposes of illustration, various modifications can be made without deviating from the spirit and scope of the present invention. For example, embodiments of the present invention may be applied to many different types of databases, systems and application programs. Moreover, features of one embodiment may be incorporated into other embodiments, even where those features are not described together in a single embodiment within the present document. Accordingly, the invention is described by the appended claims.

What is claimed is:

1. An apparatus, comprising:
a FLASH memory module capable of communicating on a USB bus, including:
a first printed circuit (p.c.) board;
a first connector attached to the first p.c. board;
a second connector attached to the first p.c. board; and
a FLASH memory coupled to the p.c. board, the FLASH memory electrically coupled to the first connector, and the FLASH memory electrically isolated from the second connector.

2. The apparatus of claim 1, further comprising:
a FLASH controller coupled to the FLASH memory and coupled to the first connector, the FLASH controller electrically interposed between the FLASH memory and the first connector.

3. The apparatus of claim 1, wherein:
the FLASH memory is a single integrated circuit.

4. The apparatus of claim 1, wherein:
the FLASH memory is a set of multiple integrated circuits.

5. The apparatus of claim 1, wherein:
the first p.c. board has a first surface and a second surface, the second surface opposite the first surface, the first connector and the second connector both attached to the first surface;
and further comprising:
a third connector attached to the second surface of the first p.c. board, the third connector electrically coupled to the second connector and physically aligned with the second connector.

6. The apparatus of claim 5, further comprising:
a fourth connector attached to the second surface of the first p.c. board, the fourth connector electrically coupled to the first connector and physically aligned with the first connector.

7. The apparatus of claim 5, further comprising:
a second p.c. board having a first surface and a second surface, the second surface opposite the first surface;
a fifth connector attached to the first surface of the second p.c. board and connected to the third connector; and
a FLASH memory coupled to the second p.c. board, the FLASH memory electrically coupled to the fifth connector.

8. The apparatus of claim 7, further comprising:
a sixth connector attached to the first surface of the second p.c. board,
the sixth connector electrically isolated from the FLASH memory,
the sixth connector connected to the fourth connector.

9. The apparatus of claim 8, further comprising:
a seventh connector attached to the second surface of the second p.c. board,
the seventh connector electrically coupled to the sixth connector,
the seventh connector physically aligned with the sixth connector.

10. The apparatus of claim 9, further comprising:
an eighth connector attached to the second surface of the second p.c. board,
the eighth connector electrically coupled to the fifth connector,
the eighth connector physically aligned with the fifth connector.

11. The apparatus of claim 7, wherein:
the first p.c. board is in a first configuration and the second p.c. board is in a second configuration.

12. The apparatus of claim 11, wherein:
the first configuration is related to the second configuration by way of a 180 degree physical rotation.

13. The apparatus of claim 11, wherein:
the first configuration and the second configuration are determined through physical configuration of a first component attached to the first p.c. board and a second component attached to the second p.c. board.

14. The apparatus of claim 7, wherein:
the first p.c. board and attached components provide a first addressable drive; and
the second p.c. board and attached components provide a second addressable drive.

15. The apparatus of claim 1, wherein:
the first connector includes connections for a USB bus; and
the second connector includes connections for a USB bus.

16. An apparatus, comprising:
a USB compatible module, including
a printed circuit (p.c.) board;
a first connector physically connected to the p.c. board;
a second connector physically connected to the p.c. board; and
an active component coupled to the p.c. board, the active component electrically coupled to the first connector, and the active component electrically isolated from the second connector.

17. The apparatus of claim 16, wherein:
the active component is FLASH memory.

18. The apparatus of claim 17, further comprising:
a FLASH controller coupled to the FLASH memory and coupled to the first connector, the FLASH controller electrically interposed between the FLASH memory and the first connector.

19. The apparatus of claim 16, wherein:
the p.c. board has a first surface and a second surface, the first surface opposite the second surface, the first connector and the second connector both connected to the first surface;
and further comprising:
a third connector connected to the second surface of the p.c. board, the third connector electrically coupled to the second connector and physically aligned with the second connector; and
a fourth connector connected to the second surface of the p.c. board, the fourth connector electrically coupled to the first connector and physically aligned with the first connector.

20. An apparatus, comprising:
means for supporting components;
first means for connecting attached to the means for supporting components, the first means for communicating with a USB bus;
second means for connecting attached to the means for supporting components; and
means for storing data, the means for storing data electrically coupled to the first means for connecting, the means for storing data electrically isolated from the second means for connecting.
